(19) United States
(12) Patent Application Publication
(10) Pub. No.: US 2015/0050778 A1
(43) Pub. Date: Feb. 19, 2015

(54) METHOD AND APPARATUS FOR PRODUCING SEMICONDUCTOR DEVICE

(71) Applicant: TORAY Industries, Inc., Tokyo (JP)

(72) Inventors: Noboru Asahi, Otsu-shi (JP); Toshihisa Nonaka, Otsu-shi (JP); Shoichi Niizeki, Otsu-shi (JP)

(21) Appl. No.: 14/383,494

(22) PCT Filed: Feb. 20, 2013
(86) PCT No.: PCT/JP2013/054096

§ 371 Date: Sep. 5, 2014

(30) Foreign Application Priority Data
Mar. 7, 2012 (JP) 2012-050094

(51) Int. Cl. H01L 23/00; B32B 37/00; B32B 38/00; H01L 25/065

(52) U.S. Cl. CPC H01L 24/83; H01L 24/81; H01L 25/0657; H01L 24/75; B32B 37/0046; B32B 38/004; H01L 2224/83862; H01L 2225/06517; H01L 2225/06541; H01L 2224/75253; H01L 2224/753; B32B 2307/202; B32B 2311/00; B32B 2457/14
USPC 438/108; 156/583.1

(57) ABSTRACT

Disclosed is a method for producing a semiconductor device in which solder joints are made between a semiconductor chip with bumps and a substrate with electrodes corresponding to the bumps through a thermosetting adhesive layer, the method including the successive steps of: (A) forming a thermosetting adhesive layer in advance on a surface including bumps of the semiconductor chip; (B) laying a surface on the thermosetting adhesive layer side of the semiconductor chip, on which the thermosetting adhesive layer is formed, and a substrate one upon another, followed by pre-bonding using a heat tool to obtain a pre-bonded laminate; and (C) interposing a protective film having a thermal conductivity of 100 W/mK or more between the heat tool and a surface on the semiconductor chip side of the pre-bonded laminate, melting a solder between the semiconductor chips and the substrate and simultaneously curing the thermosetting adhesive layer using the heat tool. There is provided a method and an apparatus for producing a semiconductor device, which is capable of making a satisfactory joint without causing catching of a resin of an adhesive film between bumps and electrode pads.

### TECHNICAL FIELD

The present invention relates to a method and an apparatus for producing a semiconductor device, which are used in PC and mobile terminals. More specifically, the present invention relates to a method and an apparatus for producing a semiconductor device in which solder joints are made between semiconductor chips for ICs and LSIs, and a circuit substrate such as a flexible substrate, a glass epoxy substrate, a glass substrate, a ceramics substrate, a silicon interposer, or a silicon substrate, or a semiconductor device in which solder joints are made between semiconductor chips.

### BACKGROUND ART

In recent days, in accordance with achievement of miniaturization and high density of a semiconductor device, flip-chip mounting, and three-dimensional stack mounting in which semiconductor chips are three-dimensionally stacked by a through-silicon via piercing though chips have been growing as the method for mounting semiconductor chips on a circuit substrate. As the method to ensure connection reliability of the joint portion between semiconductor chips and a substrate, there has widely been used, as the general method, a method in which bumps formed on semiconductor chips are joined with electrode pads of a substrate, and then a liquid sealing adhesive is injected into the space between the semiconductor chips and a circuit substrate, followed by curing.

There has recently been proposed a method in which a resin film is temporarily bonded with a semiconductor wafer with bumps and a semiconductor wafer is diced into individual semiconductor chips, and then the semiconductor chips are flip-chip jointed to a circuit substrate, and electrical joining and resin sealing are simultaneously performed, and an adhesive film used therefor (see, for example, Patent Literatures 1 to 3). According to these methods, it is possible to make a bonding area between the adhesive film and the semiconductor chips to be almost the same, leading to very little extrusion of an adhesive to the semiconductor chips as compared with the case of using a liquid sealing adhesive. When thin semiconductor chips are joined on a substrate through such adhesive film, an proposal is made to take a measure so as not to cause adhesion of the extruded adhesive to a heat tool by interposing a resin film made of Teflon (registered trademark), silicone, or the like into the space between semiconductor chips and a heat tool of a bonding device. A proposal is also made to use, as a protective film thereof, a protective film having a large elastic modulus so as to suppress warp of the semiconductor chips (see, for example, Patent Literatures 4 to 5). A proposal is also made on a method to prevent extrusion of an adhesive, and jamming of an insulating inorganic filler and a resin contained in an adhesive film between bumps of semiconductor chips and electrode pads on a substrate by defining the size of an adhesive film in the case of thermal compression bonding (see Patent Literature 6).

### CITATION LIST

### Patent Literature

### [Patent Literature 1]

Japanese Unexamined Patent Publication (Kokai) No. 2001-237268 (claim 1, pages 3 to 4)

### [Patent Literature 2]

Japanese Unexamined Patent Publication (Kokai) No. 2004-315688 (claims)

### [Patent Literature 3]

Japanese Unexamined Patent Publication (Kokai) No. 2004-319823 (claims)

### [Patent Literature 4]

Japanese Unexamined Patent Publication (Kokai) No. 2006-229124 (claims)

### [Patent Literature 5]

Japanese Unexamined Patent Publication (Kokai) No. 2009-116326 (claims)

### [Patent Literature 6]

Japanese Unexamined Patent Publication (Kokai) No. 2010-226098 (claims)

### SUMMARY OF INVENTION

### Technical Problem

However, there was a problem that, in the case of making solder joints through an adhesive film using a protective film thereof, a resin of the adhesive film is caught between bumps and electrode pads to cause continuity failure.

An object of the present invention is to provide a method and an apparatus for producing a semiconductor device, which is capable of satisfactory making solder joints without causing catching of a resin of an adhesive film between bumps and electrode pads, and contamination of a heat tool.

### Solution to Problem

A first method for producing a semiconductor device of the present invention is a method for producing a semiconductor device in which solder joints are made between semiconductor chips with bumps and a substrate with electrodes corresponding to the bumps through a thermosetting adhesive layer, the method including the successive steps of:

(A) forming a thermosetting adhesive layer in advance on a surface including bumps of the semiconductor chip;
(B) laying a surface on the thermosetting adhesive layer side of the semiconductor chip, on which the thermosetting adhesive layer is formed, and a substrate one upon another, followed by pre-bonding using a heat tool to obtain a pre-bonded laminate; and
(C) interposing a protective film having a thermal conductivity of 100 W/mK or more between the heat tool and a surface on the semiconductor chip side of the pre-bonded laminate, melting a solder between the semiconductor chips and the substrate and simultaneously curing the thermosetting adhesive layer using the heat tool.

A second method for producing a semiconductor device of the present invention is a method for producing a semiconductor device according to claim 1, wherein solder joints are made between a plurality of semiconductor chips with bumps and through-silicon vias, and a substrate with electrodes corresponding to the bumps through a thermosetting adhesive layer, the method including the successive steps of:

(A′) forming a thermosetting adhesive layer in advance on each surface including bumps of a plurality of semiconductor chips to obtain a plurality of semiconductor chips on which the thermosetting adhesive layer is formed,
(B′) obtaining a multistage pre-bonded laminate by passing through the step of laying a surface on the thermosetting adhesive layer side, on which the thermosetting adhesive layer is formed, of one semiconductor chip and a substrate one upon another, followed by pre-bonding using the heat tool, and one or more step(s) of laying a surface on the semiconductor chip side of the semiconductor chips and a surface on the thermosetting adhesive layer side of the other semiconductor chips, on which the thermosetting adhesive layer is formed, one upon another, followed by pre-bonding using the heat tool, and
(C′) interposing a protective film having a thermal conductivity of 100 W/mK or more between the heat tool and a surface on the semiconductor chip side of the multistage pre-bonded laminate, melting a solder between a plurality of semiconductor chips, and a solder between the semiconductor chips and the substrate, and simultaneously curing the thermosetting adhesive layer using the heat tool.

An apparatus for producing a semiconductor device of the present invention is an apparatus for producing a semiconductor device by bonding a substrate with a semiconductor chip, including a bonding device including a stage for disposing the substrate and a heat tool having a mechanism for heating and pressurizing the semiconductor chip; a supply reel for supplying a protective film having a thermal conductivity of 100 W/mK or more; and a take-up reel for taking up the protective film; which are disposed so that the protective film supplied from the supply reel passes between the heat tool and the stage, thus being taken up by the take-up reel.

### Advantageous Effects of Invention

According to the production method of the present invention, it is possible to easily make solder joints between bumps and electrode pads through a thermosetting adhesive layer, thus making it possible to produce a semiconductor device in a high yield.

### BRIEF DESCRIPTION OF THE DRAWINGS

FIG. 1 is a sectional view showing a mounting step of a semiconductor device using a protective film according to the present invention.

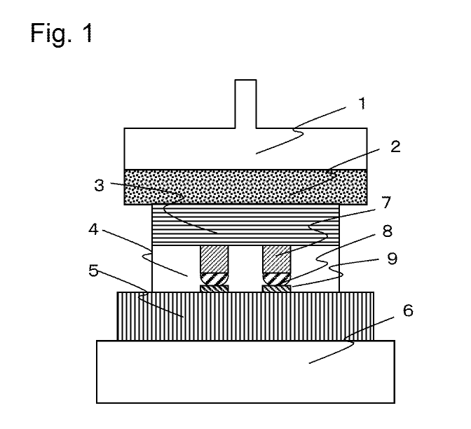

FIG. 2 is an explanatory drawing of a method for producing a semiconductor device according to the present invention.

FIG. 3 is an explanatory drawing of a method for producing a semiconductor device according to the present invention.

FIG. 4 is an explanatory drawing of a method for producing a semiconductor device in which three-dimensional stack mounting according to the present invention is performed.

### DESCRIPTION OF EMBODIMENTS

“Semiconductor device” as used in the present invention means all devices capable of functioning by making use of properties of a semiconductor device. All of an electro-optical device in which semiconductor chips are connected to a substrate, a semiconductor circuit substrate, and electronic components including them are included in the semiconductor device. The semiconductor device also includes those obtained by three-dimensionally laminating a plurality of silicon chips using semiconductor chips in which connection terminals such as electrode pads and bumps are formed on both surfaces of silicon chips including a through-silicon via (TSV).

Examples of the semiconductor chip include, but are not limited to, an integrated circuit, a large-scale integrated circuit, a transistor, a thyristor, a diode, and the like. It is possible to use, as the material of the semiconductor chip, semiconductors such as silicon (Si) and germanium (Ge); and compound semiconductors such as gallium arsenide (GaAs), gallium phosphide (GaP), indium phosphide (InP), and silicon carbide (SiC).

Bumps are formed on the semiconductor chip from the viewpoint of connection reliability. There is no particular limitation on the material of bumps, and it is possible to use metals which can be usually used in the semiconductor device, such as aluminum, copper, titanium, tungsten, chromium, nickel, gold, solder, and alloys using the same. Since there is a need to make solder joints between bumps of the semiconductor chip and electrode pads of a substrate, the material of either the bumps or the electrode pad is preferably a solder. In the present invention, heating is performed from the semiconductor chip side by a heat tool, and thus bumps are preferably solder bumps because heat easily transfers to the solder.

There is no particular limitation on the material of the solder, and it is preferred to use lead-free solders such as Sn—Ag—Cu based, Sn—Cu based, Sn—Ag based, Sn—Ag—Cu—Bi based, Sn—Zn—Bi based, and Sn—Ag—In—Bi based solders from the viewpoint of an adverse influence on the human body and environment. In order to respond narrow-pitch bumps, solder bumps are preferably formed on a pillar made of metal, especially a copper pillar. It is also possible to provide a barrier metal layer for suppressing diffusion of metal between the solder and the metal pillar. From the viewpoint of the fact that it is difficult to catch a resin and a filler between bumps and electrode pads, solder bumps preferably have a hemispherical shape.

It is preferred that all bumps in the semiconductor chip have uniform height. Specifically, variation in height of bumps is preferably 0.5 μm or less. Variation of 0.5 μm or less enables mounting of the semiconductor chip without causing connection failure in the case of bonding bumps. More preferably, variation in height of bumps is 0.2 μm or less. It is also possible to subject bumps to grinding processing so as to decrease variation in height of bumps.

Examples of the substrate include semiconductor substrates such as a silicon substrate, a ceramics substrate, a compound semiconductor substrate, an organic circuit substrate, an inorganic circuit substrate, and those obtained by disposing constituent materials of a circuit on these substrates. It is also possible to use, as the silicon substrate, semiconductor chips including the semiconductor chips, especially those having a TSV structure. In this case, plural semiconductor chips are joined with each other. In the method of the present invention, regardless of kinds of members to be used, a member in contact with a heat seal through a protective film is called a “semiconductor chip”, while a member disposed on the below-mentioned is called a “substrate”. Examples of the organic circuit substrate include glass base copper clad laminates such as a glass cloth epoxy copper clad laminate; composite copper clad laminates such as a glass nonwoven fabric epoxy copper clad laminate; heat-resistant thermoplastic substrates such as a polyetherimide resin substrate, a polyether ketone resin substrate, and a polysulfone-based resin substrate; polyester copper clad film substrates; and flexible substrates such as a polyimide copper clad film substrate. Examples of the inorganic circuit substrate include ceramic substrates such as an alumina substrate, an aluminum nitride substrate, and a silicon carbide substrate; and metal-based substrates such as an aluminum-based substrate and an iron-based substrate. Especially, the present invention effectively acts when using a silicon substrate used in a thinned multilayer substrate having a high thermal conductivity, especially semiconductor chips having a TSV structure.

Examples of the constituent material of a circuit on the substrate include a conductor containing metals such as silver, gold, copper, and aluminum; a resistor containing an inorganic oxide, and the like; a low dielectric material containing a glass-based material and/or a resin; a high dielectric material containing a resin, high dielectric constant inorganic particles, and the like; and an insulator containing a glass-based material.

The substrate includes electrode pads corresponding to the position of bumps of the semiconductor chip. The electrode pad may have a flat shape, or may be a protrusion of a so-called pillar shape (columnar). The electrode pad may have either a circular shape, or a polygonal shape such as square or octagon. There is no particular limitation on the material of the electrode pad, and it is possible to use metals which can be usually used in the semiconductor device, such as aluminum, copper, titanium, tungsten, chromium, nickel, gold, solder, and alloys using the same. It is also possible to laminate a plurality of metals. In the case of electrode pads, like bumps, variation in height is preferably 0.5 μm or less and it is also possible to be subjected to grinding processing.

The first method for producing a semiconductor device of the present invention is a method for producing a semiconductor device in which solder joints are made between a semiconductor chip with bumps and a substrate with electrodes corresponding to the bumps through a thermosetting adhesive layer, the method comprising the successive steps of:

(A) forming a thermosetting adhesive layer in advance on a surface including bumps of the semiconductor chip;
(B) laying a surface on the thermosetting adhesive layer side of the semiconductor chip, on which the thermosetting adhesive layer is formed, and a substrate one upon another, followed by pre-bonding using a heat tool to obtain a pre-bonded laminate; and
(C) interposing a protective film having a thermal conductivity of 100 W/mK or more between the heat tool and a surface on the semiconductor chip side of the pre-bonded laminate, melting a solder between the semiconductor chip and the substrate and simultaneously curing the thermosetting adhesive layer using the heat tool.

In the step (A), a thermosetting adhesive layer is formed in advance on a surface including bumps of the semiconductor chip. A particularly preferred method is a method comprising the successive steps of laying a surface on the thermosetting adhesive layer side of a thermosetting adhesive film in which a thermosetting adhesive layer is formed on a releasable plastic film, and a surface on the bump side of semiconductor chips with bumps one upon another, and performing heat lamination or vacuum heating lamination while pressurizing because of its simple operation and less extrusion of an adhesive to semiconductor chips. The temperature at the time of lamination is preferably 60° C. or higher in view of followability to irregularity of the thermosetting adhesive layer. In order to prevent curing of a thermosetting adhesive at the time of lamination, the temperature is preferably set at 100° C. or lower. The dynamic viscosity of the thermosetting adhesive layer is preferably 50 to 5,000 Pa·s within this temperature. It is easy to handle when the dynamic viscosity of the thermosetting adhesive layer is 50 Pa·s or more, while bumps are likely to be embedded in the thermosetting adhesive layer, thus enabling lamination under a low pressure when the dynamic viscosity is 5,000 Pa·s or less. In this case, a releasable plastic film of the thermosetting adhesive film is peeled off, leading to exposure of the thermosetting adhesive layer until the bonding step after the lamination step.

The dynamic viscosity of the thermosetting adhesive layer can be measured by a dynamic viscoelastic method using, for example, a rheometer (DMS6100, manufactured by Seiko Instruments Inc.).

It is also possible to form a thermosetting adhesive layer by coating a surface including bumps of the semiconductor chip with a liquid thermosetting adhesive, as the other method. There is no particular limitation on the coating method, and it is possible to use a spinner, screen printing, a blade coater, a die coater, and the like. In this case, the thermosetting adhesive layer is preferably dried in advance from the viewpoint of handling properties of the semiconductor chip until the bonding step.

It is also possible to produce a semiconductor chip with a thermosetting adhesive layer by forming a thermosetting adhesive layer on a surface of a semiconductor wafer including bumps formed thereon, on which a lot of semiconductor chips are formed, and dicing the semiconductor wafer, together with the thermosetting adhesive layer in place of performing the above-mentioned step (A) to individual semiconductor chips, respectively. This method is preferable since the thermosetting adhesive layer and the semiconductor chip can be formed into the same shape, thus minimizing extrusion of the thermosetting adhesive layer during bonding.

The thermosetting adhesive layer may be made only of an insulating resin, or the insulating resin may contain other components. A plurality of kinds of insulating resins may be mixed. It is possible to use, as the insulating resin, a polyimide resin, an epoxy resin, an acrylic resin, a phenoxy resin, a polyethersulfone resin, and the like, but the insulating resin is not limited thereto. The thermosetting adhesive layer may further contain a curing agent, a curing accelerator, and the like. It is possible to use, as the curing agent and curing accelerator, known curing agents and curing accelerators.

The thermosetting adhesive layer preferably contains an insulating inorganic filler from the viewpoint of insulation reliability and reliability to temperature cycle. It is possible to use, as the insulating inorganic filler, silica, silicon nitride, alumina, aluminum nitride, titanium oxide, titanium nitride, barium titanate, and the like. Since the insulating inorganic filler may be sometimes caught between the bumps and the electrode pad, the thermosetting adhesive layer can be preferably produced by using a method for producing a semiconductor device of the present invention.

If necessary, a crosslinking agent, a surfactant, a dispersing agent, and the like may be contained in the thermosetting adhesive layer. The thermosetting adhesive layer may have photosensitivity. In the case of having photosensitivity, after formation of a coating film or sticking of a sheet, patterning is performed by exposure and development, thus enabling opening of the requisite portion such as bump formation portion.

It is possible to use, as the thermosetting adhesive used in the present invention, resin compositions disclosed, for example, in Japanese Unexamined Patent Publication (Kokai) No. 2004-319823, Japanese Unexamined Patent Publication (Kokai) No. 2008-94870, Japanese Patent No. 3995022, Japanese Unexamined Patent Publication (Kokai) No. 2009-262227, and the like.

The thickness of the thermosetting adhesive layer is preferably an average height or more of bumps. More preferably, the thickness is an average height or more of bumps, and is also 1.5 times or less the thickness obtained by adding an average height of bumps and an average height of an electrode pad on a substrate. Still more preferably, the thickness is an average height or more of bumps, and is also the thickness or less obtained by adding an average height of bumps and an average height of an electrode pad on a substrate. It is possible to obtain the height of bumps or the height of an electrode pad by measuring the shape of a surface of semiconductor chips or substrate, and measuring a peak value of the height using the lowest height (0 μm) as standards. The average height and the average height of the electrode pad are respectively an average of the heights of all bumps of semiconductor chips and an average of the heights of all electrode pads on a substrate, and they can be measured, for example, by a confocal microscope (H1200, manufactured by Lasertec Corporation). When the thickness of the thermosetting adhesive layer is an average height or more of bumps, voids are less likely to be generated between the thermosetting adhesive layer and the substrate after bonding, and thus a decrease in adhesive force and an adverse influence on reliability are less likely to occur. When the thickness of the thermosetting adhesive layer is 1.5 times or less the thickness obtained by adding an average height of bumps and an average height of an electrode pad on a substrate, because of not only excellent economy but also a small amount of the thermosetting adhesive layer extruded, the mounting area decreases and the extruded thermosetting adhesive layer also reaches the upper portion of semiconductor chips, thus suppressing contamination of a heat tool of the bonding device and bonding between the heat tool and semiconductor chips.

In the step (B), pre-bonding is performed. As used herein, the pre-bonding step is a step in which while semiconductor chips and a substrate are fixed using a heat tool, heat and pressure are applied so that curing of a thermosetting adhesive does not proceed. In the pre-bonding step, a surface on the thermosetting adhesive layer side of the semiconductor chip, on which the thermosetting adhesive layer is formed, and a substrate are laid one upon another, followed by pre-bonding using the heat tool to obtain a pre-bonded laminate.

In that case, after adjusting the position based on the alignment mark so that the connection position of bumps of the semiconductor chip agrees with that of the electrode pads of the substrate, pre-bonding is performed. From the viewpoint of positional accuracy, the thermosetting adhesive layer is preferably transparent so as to be able to recognize the alignment mark.

The temperature of the heat tool at the time of pre-bonding is preferably within a temperature range of 60 to 120° C. so that the viscosity of the thermosetting adhesive layer is decreased at the temperature of a solder melting point or lower to enhance adhesiveness, thus fixing semiconductor chips at the predetermined position, and curing of the thermosetting adhesive does not proceed. The pressure at the time of pre-bonding is preferably within a range of 0.01 to 0.5 MPa. The pressure of 0.01 MPa or more enables sufficient achievement of an object of pre-bonding, while the pressure of 0.5 MPa or less enables pre-bonding without causing significant deformation of bumps. Pre-bonding may be performed under a normal pressure, or may be performed in vacuum so as to prevent intrusion of bubbles. The temperature as used herein means a temperature in the thermosetting adhesive layer and can be determined, for example, by connecting a thermocouple to a temperature recorder (NR100, manufactured by Keyence Corporation).

In the case of pre-bonding, it is also possible to stick a protective film having a thermal conductivity of 100 W/mK or more to a surface in contact with the semiconductor chip of a heat tool. In this case, it is possible to continuously perform the below-mentioned main bonding step without removing a heat tool from semiconductor chips. It is also possible to stick a protective film on a stage on which a substrate is disposed so as not to contaminate the stage.

In the step (C), main bonding is performed. As used herein, a main bonding step means a step of melting a solder between a semiconductor chip and a substrate using a heat tool, and also applying heat and pressure so as to cure a thermosetting adhesive layer. In the main bonding step, a protective film having a thermal conductivity of 100 W/mK or more is interposed between the heat tool and a surface on the semiconductor chip side of a pre-bonded laminate, and a solder between the semiconductor chips and the substrate is melted and the thermosetting adhesive layer is simultaneously cured using the heat tool.

The temperature of the heat tool at the time of main bonding is preferably within a range of 220 to 300° C. so that a solder is melted. This heat treatment may be performed by stepwisely raising the temperature or continuously raising the temperature. The heating time is preferably from 1 second to several minutes. As an example, after maintaining at 100° C. for 10 seconds so as to soften the thermosetting adhesive layer, a heating treatment is performed at 250° C. for 20 seconds so as to melt solder. At this time, the heat-up time of the temperature is preferably 1 second or less from the viewpoint of fluidity of the adhesive and timing of melting of solder. The heat-up time means the time during which the surface temperature of the heat tool changes by 90% or more from the current temperature toward the setting temperature. The pressure at the time of main bonding is preferably within a range of 0.01 to 1 MPa from the viewpoint of the pushed in amount of a solder. At this time, the pressure can be temporally changed. At the time of melting a solder, it is also possible to perform height control for fixing the position of the heat tool. The heat treatment may be performed under a normal pressure or in vacuum. In order to prevent oxidative degradation due to air, the heat treatment may be performed under nitrogen atmosphere.

The protective film used in the present invention is a film having a thermal conductivity of 100 W/mK or more, and preferably 200 W/mK or more. Use of the protective film makes it possible to prevent the heat tool from contaminating with the thermosetting adhesive. Contamination of the heat tool causes impaired smoothness of the heat tool, leading to non-uniform thermally bonded state of semiconductor chips at the time of bonding, resulting in generation of bonding failure. Use of the protective film enables prevention of such problem. When the protective film has thermal conductivity of 100 W/mK or more, it becomes possible to transfer heat from the heat tool to solder bumps of semiconductor chips or solder electrode pads of a substrate in a short time. As a result, it becomes possible to melt a solder in a state where the thermosetting adhesive layer has fluidity before curing. It is possible to join bumps with electrode pads without causing catching of a resin contained in the thermosetting adhesive layer. The upper limit of thermal conductivity is not particularly limited and is preferably 500 W/mK or less, and more preferably 400 W/mK or less, in view of ease of availability of a protective film.

When the protective film has thermal conductivity of less than 100 W/mK, transfer of heat from the heat tool to solder bumps or solder electrode pads takes time, and thus curing of the thermosetting adhesive layer proceeds before a solder is melted. In that case, in the case of joining bumps with electrode pads, the thermosetting adhesive having lost fluidity is caught between bumps and electrode pads.

The thickness of the protective film is preferably 5 μm or more and 20 μm or less. The thickness is preferably 5 μm or more since the strength of the protective film increases. When the thickness is 20 μm or less, the heat transfer time at the time of solder melting decreases and thus it is easy to transfer heat without curing the thermosetting adhesive layer.

It is possible to use, as the material of the protective film, various materials having a thermal conductivity of 100 W/mK or more. Of these materials, a copper foil or aluminum foil having high thermal conductivity and high workability is preferable. The copper foil may contain impurities other than copper, and the amount of impurities is preferably 10% by weight or less, and more preferably 1% by weight or less, in the total weight of the copper foil. The aluminum foil may also contain impurities other than aluminum, and the amount of impurities is preferably 10% by weight or less, and more preferably 1% by weight or less, in the total weight of the aluminum foil. The protective film may have a structure in which two or more metal foils or a film capable of prevention of sticking are laminating. It is also possible to use those with a fluorine coat (releasant). In the case of these protective films, thermal conductivity is the value as the whole laminate structure. Thermal conductivity of the protective film can be measured, for example, using Thermal Conductivity Measurement System (1μ, manufactured by ai-Phase Co., Ltd.).

After the above main bonding step, additional cure may be performed. The conditions of additional cure can be optionally set according to properties of the thermosetting adhesive to be used.

Each step of the method for producing a semiconductor device of the present invention will be described by way of Examples, but the present invention is not limited to the following Examples.

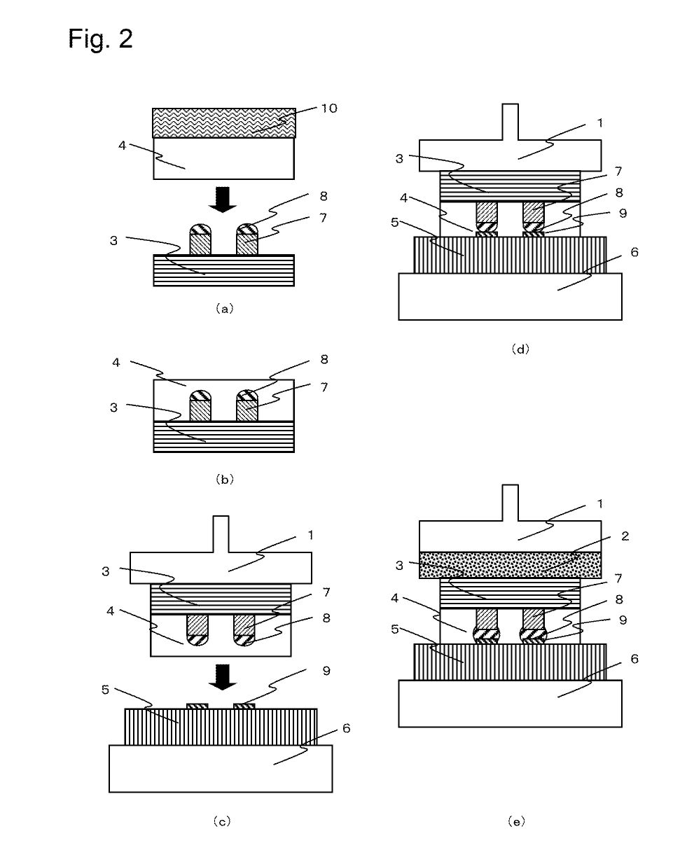

First, an example of the step (A) is shown in FIG. 2(a). In the example shown in FIG. 2(a), copper pillars 7 are provided on one surface of a semiconductor chip 3, and hemispherical solder bumps 8 are formed on copper pillars 7. On a surface on which solder bumps 8 of the semiconductor chip 3 are formed, a thermosetting adhesive film, in which a thermosetting adhesive layer 4 is formed on a plastic film 10, is laminated. A surface on the thermosetting adhesive layer 4 of the thermosetting adhesive film and a surface, on which solder bumps 8 of the semiconductor chip 3 are formed, are laid one upon another, followed by lamination by application of pressure while heating. In this case, since lamination is preferably performed without forming voids between the thermosetting adhesive layer 4 and the semiconductor chip 3, lamination is preferably performed in vacuum. The device capable of laminating in vacuum includes, for example, Vacuum & Pressure Laminator (MVLP500/600, manufactured by Meiki Co., Ltd.). At this time, heating may be performed from the semiconductor chip side or the plastic film side, or both sides. The pressure at the time of lamination is preferably 0.1 MPa or more and 1 MPa or less so that the thermosetting adhesive layer 4 can follow irregularity of solder bumps 8 and solder bumps 8 are not collapsed. After lamination, a plastic film 10 is removed from the thermosetting adhesive layer 4, thus making it possible to obtain a semiconductor chip on which the thermosetting adhesive layer 4 is formed (FIG. 2(b)).

Next, an example of the pre-bonding step as the step (B) is shown in FIG. 2(c). For pre-bonding, a flip-chip bonder, for example, a bonding device FC3000S (manufactured by Toray Engineering Co., Ltd.) is used. A substrate 5 is disposed on a stage 6 of the bonding device and the semiconductor chip, on which the thermosetting adhesive layer 4 is formed, is conveyed to the upper direction of the substrate using a heat tool 1, whereby, a bump formation surface of the substrate 5 and a surface on the thermosetting adhesive layer 4 of the semiconductor chip face each other. In this case, a protective film 2 may be interposed in advance between the heat tool 1 and the semiconductor chip 3. The stage 6 may be maintained in advance at a given temperature of 40° C. or higher and 100° C. or lower so that ambient temperature environmental conditions exert no influence and curing of the resin does not proceed. Next, positioning is performed by detecting the respective alignment marks of the semiconductor chip 3 and the substrate 5 area so that the connection position of solder bumps 8 of the semiconductor chip agrees with that of the electrode pads 9 of the substrate. The heat tool 1 is provided with a mechanism for heating and pressurizing the semiconductor chip 3 and the semiconductor chip 3 is pressed against the substrate 5 while heating (FIG. 2(d)). At this time, heat transfers to a thermosetting adhesive layer 4 through the semiconductor chip 3. Accordingly, the temperature of the thermosetting adhesive layer 4 rises to cause an increase in fluidity, and thus bonding the semiconductor chip 3 and the substrate 5 to obtain a pre-bonded laminate.

Next, a main bonding step shown in FIG. 2(e) is performed. In the main bonding step, like the case of pre-bonding, the semiconductor chip 3 is pressed against the substrate while heating using a heat tool 1, and the temperature of the heat tool 1 is controlled so that the thermosetting adhesive layer 4 is cured and also a solder of solder bumps 8 is melted. A protective film 2 having a thermal conductivity of 100 W/mK or more is interposed between the heat tool 1 and the semiconductor chip 3.

In the present invention, since a protective film 2 having a high thermal conductivity is used, a solder is melted before curing of the thermosetting adhesive layer 4 because of quick thermal conduction from the heat tool 1. Therefore, the thermosetting adhesive layer 4 maintains fluidity at the time of melting of a solder, thus enabling satisfactory joining between the solder bump 8 and the electrode pad 9. Even if the adhesive is extruded, the protective film 2 exists between the heat tool 1 and the semiconductor chip 3, thus enabling bonding without causing contamination of the heat tool 1 with the adhesive. In order to allow curing of the thermosetting adhesive layer 4 to proceed, heating may be further heated after the main bonding step.

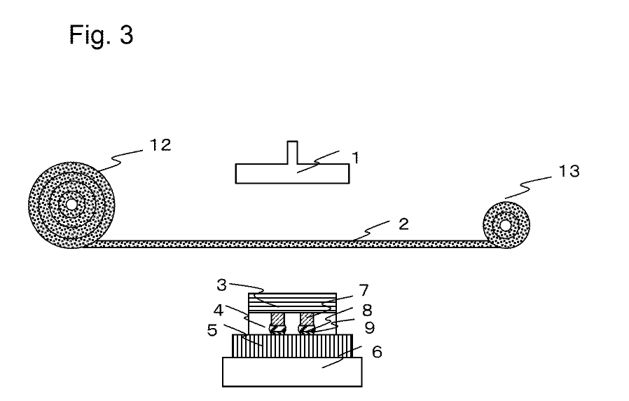

The protective film 2 may be stuck in advance on the heat tool 1, or may be inserted between the semiconductor chip 3 and the heat tool 1 at the time of bonding. As shown in FIG. 3, the protective film 2 is preferably supplied in a reel-to reel manner since it becomes easy to supply a new surface of the protective film 2 between the semiconductor chip 3 and the heat tool 1. In the device of FIG. 3, the protective film 2 is supplied from a supply reel 12 and is disposed so that it passes between the heat tool 1 and the semiconductor chip 3 in the bonding device, and then taken up by a take-up reel 13. One of preferred aspects is as follows. That is, the supply reel 12 and the take-up reel 13 are driven according to an operation of the bonding device, and the supply reel 12 and the take-up reel 13 are driven every single bonding operation, thus supplying a new surface of the protective film 2 between the heat tool 1 and the semiconductor chip 3. The reel is not driven every single bonding operation, but may be driven every multiple bonding operation. Anew surface of the protective film 2 may be continuously supplied little by little by continuously driving the reel at a given rate.

A second method for producing a semiconductor device of the present invention is a method for producing a semiconductor device, wherein solder joints are made between a plurality of semiconductor chips with bumps and through-silicon vias, and a substrate with electrodes corresponding to the bumps through a thermosetting adhesive layer, the method including the successive steps of:

(A′) forming a thermosetting adhesive layer in advance on each surface including bumps of a plurality of semiconductor chips to obtain a plurality of semiconductor chips on which the thermosetting adhesive layer is formed,
(B′) obtaining a multistage pre-bonded laminate by passing through the step of laying a surface on the thermosetting adhesive layer side, on which the thermosetting adhesive layer is formed, of one semiconductor chip and a substrate one upon another, followed by pre-bonding using a heat tool, and one or more step(s) of laying a surface on the semiconductor chip side of the semiconductor chips and a surface on the thermosetting adhesive layer side of the other semiconductor chips, on which the thermosetting adhesive layer is formed, one upon another, followed by pre-bonding using a heat tool, and
(C′) interposing a protective film having a thermal conductivity of 100 W/mK or more between the heat tool and a surface on the semiconductor chip side of the multistage pre-bonded laminate, melting a solder between a plurality of semiconductor chips, and a solder between the semiconductor chips and the substrate, and simultaneously curing the thermosetting adhesive layer using the heat tool.

First, in the step (A′), a thermosetting adhesive layer is formed in advance on a surface including bumps of the semiconductor chips. It is possible to use, as the method for forming a thermosetting adhesive layer, the same method as the first production method. In the present production method, a laminate of chips is formed in a multi-stage manner. Therefore, it is particularly preferred to use chips obtained by forming a thermosetting adhesive layer on a semiconductor wafer, and simultaneously dicing the thermosetting adhesive layer and the semiconductor wafer since extrusion of the thermosetting adhesive layer from the obtained laminate can be minimized.

Next, in the step (B′), pre-bonding is performed. In the pre-bonding step, first, in the same manner as in the first production method, after laying a surface on the thermosetting adhesive layer side of one semiconductor chip, on which a thermosetting adhesive layer is formed, and a substrate one upon another, pre-bonding is performed by heating and pressurizing using a heat tool of a bonding device. Furthermore, after laying a surface on the semiconductor chip side of the pre-bonded semiconductor chips and a surface on the thermosetting adhesive layer side of other semiconductor chips on which a thermosetting adhesive layer is formed one upon another, pre-bonding is performed. This step is repeated to form a multistage pre-bonded laminate in which a plurality of semiconductor chips are laminated and pre-bonded.

While preferred temperature conditions of the heat tool of pre-bonding are the same as in the first production method, it is possible to change the temperature every number of stages of lamination since heat transfer from the heat tool varies when the number of stages of lamination increases.

In the case of pre-bonding, it is also possible to stick a protective film having a thermal conductivity of 100 W/mK or more to a surface in contact with the semiconductor chip of the heat tool. In this case, the below-mentioned main bonding step (C′) can be continuously performed without removing the heat tool from the semiconductor chip.

In the main bonding step (C′), in the same manner as in the first production method, a protective film having a thermal conductivity of 100 W/mK or more is interposed between a heat tool and a surface on the semiconductor chip side of a multistage pre-bonded laminate, and a solder between a plurality of semiconductor chips and a solder between the semiconductor chips and the substrate are melted and the thermosetting adhesive layer is cured, simultaneously. It is also possible to lay a surface on the thermosetting adhesive layer side of other semiconductor chips on which a thermosetting adhesive layer is further formed thereon to form a multistage pre-bonded laminate by the step (B′), followed by a main bonding step (C′).

Each step of a second production method will be described below by way of examples, but the present invention is not limited to the following examples.

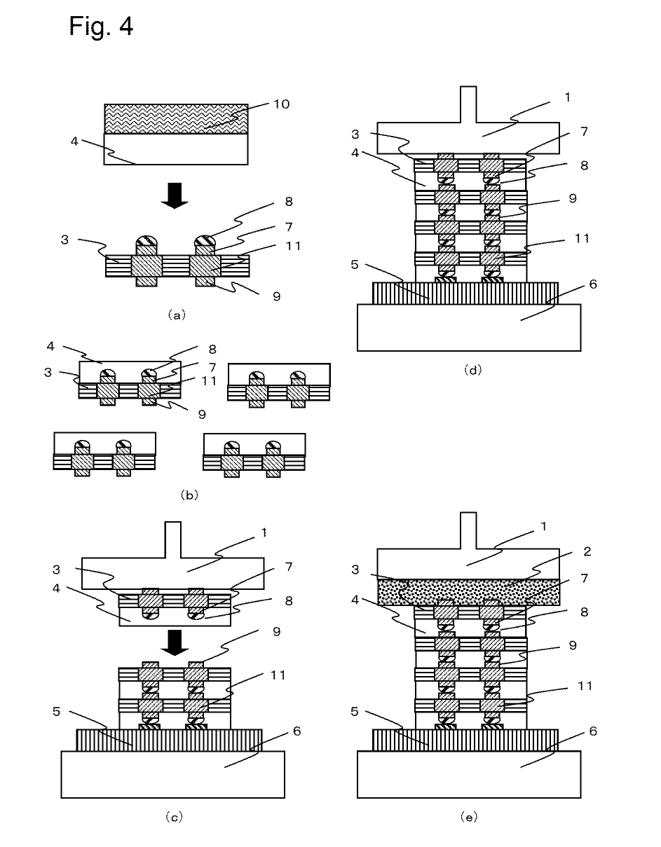

First, an example of the step (A′) is shown in FIG. 4(a). In this example, semiconductor chips 3 including through-silicon vias (TSV) 11 are used. A copper pillar 7 is provided on TSV 11 on one surface of the semiconductor chips 3 including TSV 11, while hemispherical solder bumps 8 are formed on the copper pillar 7. On TSV 11 on the opposite surface, electrode pads 9 is formed. In the same manner as in the first production method, on a surface on which solder bumps 8 of semiconductor chips 3 are formed, a thermosetting adhesive film, on which a thermosetting adhesive layer 4 is formed on a plastic film 10, is laminated, and then the plastic film 10 is peeled off to form the thermosetting adhesive layer 4 on the surface on which solder bumps 8 of semiconductor chips 3 are formed.

On a surface including bumps 8 of a plurality of semiconductor chips 3, a thermosetting adhesive layer 4 is formed in accordance with the step (A′), thus obtaining a plurality of semiconductor chips in which a thermosetting adhesive layer is formed (FIG. 4(b)).

Next, a surface on thermosetting adhesive layer side of one semiconductor chip, on which a thermosetting adhesive layer 4 is formed, and a substrate 5 are laid one upon another, followed by pre-bonding in the same manner as in the first production method. As shown in FIG. 4(c), a surface on the semiconductor chip side of pre-bonded semiconductor chips is laid on a surface on the thermosetting adhesive layer 4 side of other semiconductor chips 3 on which a thermosetting adhesive layer 4 is formed, followed by pre-bonding. Thus step is repeated to form a multistage pre-bonded laminate in which a plurality of semiconductor chips are laminated and pre-bonded (FIG. 4(d)).

Finally, in the same manner as in the first production method, a protective film 2 having a thermal conductivity of 100 W/mK or more is interposed between a heat tool 1 and a surface on the semiconductor chip side in the multistage pre-bonded laminate, and a solder between a plurality of semiconductor chips and a solder between the semiconductor chips and the substrate are melted and a main bonding step of curing the thermosetting adhesive layer is performed, simultaneously (FIG. 4(e)).

### EXAMPLES

A method for producing a semiconductor device of the present invention will be more specifically described below, but the present invention is not limited thereto.

The present invention will be described below by way of Examples, but the present invention is not limited to these Examples. Materials and evaluation methods used in Examples 1 to 14 and Comparative Examples 1 to 6 are shown below.

### <Structure of Semiconductor Chip>

A 1 μm thick aluminum wiring was formed on an oxide film of a silicon wafer, and a 1 μm thick silicon nitride insulating film was formed thereon. The silicon nitride insulating film was provided with an opening so as to have continuity with the silicon wafer. The opening was formed with a chromium layer, and then a copper post having a height of 10 μm and a bump having a height of 5 μm made of a solder (SnAg) hemisphere were formed on the chromium layer to produce a semiconductor chip. Four kinds of bumps, each having a bump diameter of 25 μm, 30 μm, 35 μm, or 40 μm, were provided in one semiconductor chip. Four kinds of bumps, each having a bump pitch of 75 μm, 80 μm, 85 μm, or 90 μm relative to each bump diameter, were provided. The number of bumps provided was 174, 162, 150, and 138, to each pitch. Aluminum wiring is patterned on semiconductor chips so as to be able to measure connection resistance for each bump structure after mounting on the substrate. A lot of semiconductor chips are formed on one silicon wafer, and each semiconductor chip has a size of 7 mm×7 mm and a thickness of 100 μm. Each semiconductor chip is formed with an alignment mark for positioning.

### <Substrate>

A 1 μm thick aluminum wiring was formed on an oxide film of a silicon substrate (film thickness of 100 μm), and a 1 μm thick silicon nitride insulating film was formed thereon. The silicon nitride insulating film was provided with an opening so as to have continuity with the silicon substrate. The opening was formed with a chromium layer, and then an electrode pad made of copper having a film thickness of 5 μm and nickel/gold having a film thickness of 1 μm was formed on the chromium layer to produce a substrate. Both the position and the diameter of the electrode pad formed are set so as to correspond to the bump of the semiconductor chip. The substrate has a size of 12 mm×12 mm and a thickness of 100 μm, and a pad of an extraction electrode of 2 mm square is formed in the region where the chip on the substrate is not mounted. A daisy chain is formed by mounting the above-mentioned semiconductor chip on the substrate, and junction resistance between the bump and the electrode pad can be measured through the extraction electrode. The substrate is formed with an alignment mark for positioning.

### <Protective Film>

An aluminum foil and a copper foil were used as a protective film having a thermal conductivity of 100 W/mK or more. A fluororesin film and an iron foil were used as a protective film having a thermal conductivity of less than 100 W/mK. The thermal conductivity measured by using Thermal Conductivity Measurement System (1μ, manufactured by ai-Phase Co., Ltd.) was 230 W/mK for aluminum foil, 400 W/mK for copper foil, 0.25 W/mK for fluororesin film, and 70 W/mK for iron foil. Aluminum foil each having a film thickness of 6 μm, 12 μm, or 18 μm; copper foils each having a film thickness of 3 μm, 5 μm, 18 μm, or 30 μm; fluororesin films each having a film thickness of 12 μm or 30 μm; and an iron foil having a film thickness of 20 μm were used.

### <Formation of Thermosetting Adhesive Film>

After mixing a polyimide (a), an epoxy resin (b), and a curing accelerator (c) mentioned below, a solvent (d) was added while appropriately adjusting so as to obtain a coating film having a uniform thickness, thus obtaining a thermosetting adhesive. The thermosetting adhesive was applied on a releasable plastic film (polyethylene terephthalate film) and then dried to form a thermosetting adhesive film 1 in which a thermosetting adhesive layer is formed on a plastic film. Mixing was performed so that a ratio of the polyimide (a), the epoxy resin (b), and the curing accelerator (c) becomes 50:20:50 in terms of a weight ratio. The thermosetting adhesive layer had a thickness of 25 μm.

After mixing a polyimide (a), an epoxy resin (b), a curing accelerator (c), and an insulating filler (e) mentioned below, a solvent (d) was added while appropriately adjusting so as to obtain a coating film having a uniform thickness, thus obtaining a thermosetting adhesive. The thermosetting adhesive was applied on a releasable plastic film (polyethylene terephthalate film) and then dried to form a thermosetting adhesive film 2 in which a thermosetting adhesive layer is formed on a plastic film. Mixing was performed so that a ratio of the polyimide (a), the epoxy resin (b), the curing accelerator (c), and the insulating filler (e) becomes 25:10:25:50 in terms of a weight ratio. The thermosetting adhesive layer had a thickness of 25 μm.

The curing accelerator (c) is prepared by dispersing a microcapsule type curing accelerator in an epoxy resin, and a weight ratio of the microcapsule type curing accelerator to the epoxy resin is 33/67. However, in the above mixing ratio, the proportion of the curing accelerator (c) is calculated based on the entire amount of the curing accelerator (c). The epoxy resin in the curing accelerator (c) is not included in the proportion of the epoxy resin (b).

### (a) Polyimide

An organic solvent-soluble polyimide synthesized by the following process was used. First, under a dry nitrogen gas flow, 24.54 g (0.067 mol) of 2,2-bis(3-amino-4-hydroxyphenyl)hexafluoropropane, 4.97 g (0.02 mol) of 1,3-bis(3-aminopropyl)tetramethyldisiloxane, and 2.18 g (0.02 mol) of 3-aminophenol as a terminal sealing agent were dissolved in 80 g of NMP. To the solution thus obtained, 31.02 g (0.1 mol) of bis(3,4-dicarboxyphenyl)ether dianhydride was added, together with 20 g of NMP, followed by the reaction at 20° C. for 1 hour and further stirring at 50° C. for 4 hours. Thereafter, 15 g of xylene was added and the reaction solution was stirred at 180° C. for 5 hours while making water to azeotripic, together with xylene. After completion of the stirring, the solution was poured into 3 L of water to obtain a polymer as a white precipitate. This precipitate was collected by filtration, washed three times with water, and then dried at 80° C. for 20 hours using a vacuum dryer.

### (b) Epoxy Resin

A solid epoxy compound (epoxy resin 157S70, manufactured by Mitsubishi Chemical Corporation) was used.

### (c) Curing Accelerator

A microcapsule type curing accelerator (NOVACURE (registered trade name) HX-3941HP, manufactured by Asahi Kasei Chemicals Corp.) was used.

### (d) Solvent

A mixture of methyl ethyl ketone and toluene (=4/1 in terms of a weight ratio) was used.

### (e) Insulating Inorganic Filler

SO-E2 (trade name, spherical silica particles, average particle diameter of 0.5 μm, manufactured by Admatechs Company Limited) was used.

<Production of Semiconductor Chip with Thermosetting Adhesive Film>

A thermosetting adhesive layer was embedded in bumps of a semiconductor chip using Vacuum & Pressure Laminator (MVLP500/600, manufactured by Meiki Co., Ltd.). Lamination was performed in vacuum under the conditions at 80° C. for 20 seconds under a pressure of 0.7 MPa while pressing a surface on the thermosetting adhesive layer side of the thermosetting adhesive film thus formed as mentioned above against a bump formation surface of a silicon wafer on which a lot of semiconductor chips are formed. The excessive thermosetting adhesive film on the periphery of the silicon wafer was cut by a cutter. The silicon wafer used herein has a size of 8 inch.

Next, using a wafer mounter (FM-1146-DF, manufactured by TECHNOVISION, INC.), a surface on the opposite side from bumps of a semiconductor wafer substrate, on which a thermosetting adhesive layer is formed, and a dicing tape (D-650, manufactured by Lintec Corporation) stuck on a tape frame are laid one upon another. After removing a polyethylene terephthalate film from the thermosetting adhesive layer, the tape frame was fixed on a cutting stage of a dicing device (DFD-6240, manufactured by DISCO Corporation) so that the surface of the thermosetting adhesive layer faces upward. Then, dicing was performed under the following cutting conditions.

### Blade: NBC-ZH 127F-SE 27HCCC

Spindle speed: 25,000 rpm
Cutting speed: 50 mm/s
Cutting depth: cut up to depth of 20 μm of dicing tape
Cut: One-path full cut
Cut mode: Down cut
Amount of cutting fluid: 3.7 L/minute
Cutting fluid and coolant: temperature of 23° C., electrical conductivity of 0.5 MΩ·cm (carbonic acid gas is injected into ultrapure water).

With regard for semiconductor chips chipped into individual pieces by dicing, adhesion of chips to a surface of a thermosetting adhesive layer, cracking or omission of a surface of a thermosetting adhesive layer, and peeling of a thermosetting adhesive film from a wafer were not observed.

### <Bonding>

Semiconductor chips with a thermosetting adhesive film obtained as mentioned above were accommodated in a chip tray with a surface, on which a thermosetting adhesive layer is formed, facing upward, and then supplied to a bonding device (FC3000S, manufactured by Toray Engineering Co., Ltd.). Meanwhile, the substrate was disposed on a state maintained at 60° C. of the bonding device.

First, semiconductor chips accommodated in the chip tray were picked up by a pick-up tool and a surface of chips was inverted. Next, a surface on the semiconductor chip side of semiconductor chips was vacuum-suctioned by a conveying device and semiconductor chips were conveyed upward of the substrate placed on the stage. Next, an alignment recognition camera enters between the semiconductor chips and substrate so that bumps of semiconductor chips and electrode pads on the substrate are laid one upon another at the predetermined position, followed by detection of each alignment mark.

After adjusting the position based on the alignment mark so that the connection position of bumps of semiconductor chips agrees with that of the electrode pad of the substrate, pre-bonding was performed by heating and pressurizing semiconductor chips under a pressure of 15N at a temperature of 100° C. for 10 seconds using a heat tool of a bonding device to produce a pre-bonded laminate.

The surface temperature of an attachment of the heat tool was calibrated in advance using a temperature recorder (NR100, manufactured by Keyence Corporation) and a K thermocouple.

Next, a protective film having a thermal conductivity of 100 W/mK or more was interposed between the heat tool and a surface on the semiconductor chip side in the pre-bonded laminate, and main bonding was performed, thereby melting a solder between the semiconductor chips and the substrate, and curing the thermosetting adhesive layer. The main bonding was performed by maintaining under a pressure of 40N at a temperature of 100° C. for 10 seconds, and then treating under a pressure of 40N at a temperature of 250° C. for 20 seconds.

### <Mountability Evaluation>

Mountability was evaluated by the measurement of continuity resistance of a daisy chain formed after mounting (continuity evaluation) and cross-sectional observation of the bump connection portion (cross-sectional observation evaluation).

It is designed that semiconductor chips and substrates used in the evaluation of each Example are electrically connected through connection portions formed in the number of 138, 150, 162, and 174 for each bump pitch. If only one portion where bumps are not in contact with the electrode pad, connection failure occurs. Here, a measuring terminal of DIGITAL VOLTMETER (3455A, manufactured by HEWLETT PACKARD) was connected and a resistance value thereof was measured. The resistance value includes not only the value of the connection portion between bumps and electrode pads, but also the value of resistance inside semiconductor chips and a lead electrode. It was judged whether or not all resistance values measured with respect to the daisy chain of each bump pitch are less than 100 kΩ. The case where all resistance values of daisy chains measured with respect to 3 samples after mounting are less than 100 kΩ was rated “A”, the case where some of resistance values of daisy chains measured with respect to 1 sample or 2 samples after mounting are more than 100 kΩ were rated “B”, and the case where all resistance values of daisy chains measured with respect to 3 samples after mounting are more than 100 kΩ was rated “C”, respectively.

Cross-sectional observation was evaluated by the following procedures. With respect to bumps observed by a microscope after cutting at any position, it was judged whether or not a resin or a filler bites at an interface between solder bumps and a copper pad on a substrate in the proportion of 10% or more relative to the diameter of a copper pad. The case where all 3 samples do not bite in the proportion of 10% or more relative to the diameter of a copper pad after mounting was rated “A”, the case where 1 sample or 2 samples bite(s) in the proportion of 10% or more relative to the diameter of a copper pad after mounting was rated “B”, and the case where all 3 samples bite in the proportion of 10% or more relative to the diameter of a copper pad after mounting was rated “C”, respectively.

### Example 1 to Example 3

Using aluminum foils, each having a thickness of 6 μm, 12 μm, or 20 μm as a protective film and using a thermosetting adhesive film 2 as a thermosetting adhesive film, mountability was evaluated by the above-mentioned method. Regarding Example 1 to Example 3, adhesion of the extruded thermosetting adhesive film to a pick-up tool was not observed, and thus both continuity and cross-sectional observation were rated “A” as a result of the evaluation. The results are shown in Table 1.

### Example 4 to Example 6

In the same manner as in Example 1 to Example 3, except that a thermosetting adhesive film 1 was used as a thermosetting adhesive film, the evaluation was performed, respectively. Both continuity and cross-sectional observation were rated “A” as a result of the evaluation. The results are shown in Table 1.

### Example 7 to Example 10

In the same manner as in Example 1, except that copper foils, each having a thickness of 3 μm, 5 μm, 18 μm, or 30 μm was used as a protective film, the evaluation was performed. When using a copper foil having a film thickness of 30 μm (Example 10), while 10% or more of biting was recognized in cross-sectional observation for 1 sample, adhesion of the extruded thermosetting adhesive film to a pick-up tool was not observed, and thus both continuity and cross-sectional observation were rated “A” as a result of the evaluation. The results are shown in Table 1.

### Example 11 to Example 14

In the same manner as in Example 7 to Example 10, except that a thermosetting adhesive film 1 was used as a thermosetting adhesive film, the evaluation was performed, respectively. Both continuity and cross-sectional observation were rated “A” as a result of the evaluation. The results are shown in Table 1.

### Example 15

A silicon substrate including TSV(s) made of copper having a diameter of 50 μm at a pitch of 200 μm formed thereon was used as the semiconductor chip. A lot of semiconductor chips are formed on one silicon wafer, and each semiconductor chip has a size of 7 mm×7 mm. Chips of 7 mm square are formed with TSV (26×27). A 1 μm thick copper wiring was formed on TSV on one surface of semiconductor chips through a 1 μm thick polyimide passivation film, and a 1 μm thick polyimide insulating film was formed thereon. The polyimide insulating film was provided with an opening so as to electrically connect to TSV, and the opening was formed with a chromium layer, and then the opening was formed with a copper post having a height of 10 μm and a bump having a height of 5 μm made of a solder (SnAg) hemisphere to produce a semiconductor chip. A bump diameter is 30 μm. After mounting on the substrate, copper wiring is patterned to each bump so as to be able to measure connection resistance. Chip has a thickness of 100 μm. On a surface on the opposite side from bumps of semiconductor chips, an opening provided on a 1 μm thick polyimide insulating film so as to be electrically connected with TSV was formed with a chromium layer, and the opening was formed with an electrode pad made of copper having a film thickness of 5 μm and nickel/gold having a film thickness of 1 μm.

On an oxide film of a silicon substrate (film thickness of 100 μm), a 1 μm thick aluminum wiring was formed and also a 1 μm thick silicon nitride insulating film was formed thereon. The opening provided on the silicon nitride insulating film so as to have continuity with silicon substrate was formed with a chromium layer, and then the opening was formed with an electrode pad made of copper having a film thickness of 5 μm and nickel/gold having a film thickness of 1 μm to produce a substrate. The electrode pads are formed so that the position and diameter thereof correspond to bumps of semiconductor chips. The substrate has a size of 12 mm×12 mm and a thickness of 100 μm, and a pad of an extraction electrode of 2 mm square is formed in the region where the chip on the substrate is not mounted. A daisy chain is formed by mounting the above-mentioned semiconductor chip on the substrate, and junction resistance between the bump and the electrode pad can be measured through the extraction electrode.

In the same manner as in the step of <Production of Semiconductor Chip with Thermosetting Adhesive Film>, except that the silicon wafer formed with TSV was used in place of the silicon wafer used in the step of <Production of Semiconductor Chip with Thermosetting Adhesive Film>, a semiconductor chip with a thermosetting adhesive layer was obtained.

In the same manner as in the pre-bonding step of the <bonding> step, except that this semiconductor chip with a thermosetting adhesive layer was used, a pre-bonded laminate in which semiconductor chips are laminated in one stage on a substrate. Furthermore, the same step was repeated three times to form a four-stage pre-bonded laminate in which the semiconductor chip is laminated in four stages on a substrate. Next, a 12 μm thick protective film of an aluminum foil was interposed between a heat tool and a surface on the semiconductor chip side in a four-stage pre-bonded laminate, followed by main bonding using the same method as in the main bonding step in the <bonding> step.

Mountability was evaluated in the same manner as in Example 1. In cross-sectional observation evaluation, regarding a semiconductor device obtained in Example 1, a semiconductor chip is produced in one stage. In the present Example, a semiconductor chip is produced in four stages and, in the present Example, a semiconductor device obtained by laminating a semiconductor chip in four stages was cut. The results are shown in Table 1.

### Comparative Examples 1 and 2

In the same manner as in Comparative Example 1, except that fluororesin films, each having a thickness of 12 μm or 30 μm, were used as a protective film, the evaluation was performed, respectively. While adhesion of the extruded thermosetting adhesive layer to a pick-up tool was not recognized, both continuity and cross-sectional observation were rated “C”. The results are shown in Table 1.

### Comparative Examples 3 and 4

In the same manner as in Comparative Examples 1 and 2, except that a thermosetting adhesive film 1 was used as a thermosetting adhesive film, the evaluation was performed, respectively. When using a protective film having a thickness of 12 μm (Comparative Example 3), all resistance values of a daisy chain were less than daisy chain 100 kΩ for only one sample in the continuity evaluation, and thus cross-sectional observation was rated “B” as a result of the evaluation. The cross-sectional observation was rated “C”. The results are shown in Table 1.

### Comparative Example 5

In the same manner as in Comparative Example 1, except that an iron foil having a thickness of 20 μm was used as a protective film, the evaluation was performed. While adhesion of the extruded thermosetting adhesive layer to a pick-up tool was not observed, both continuity and cross-sectional observation were rated “C” as a result of the evaluation. The results are shown in Table 1.

### Comparative Example 6

In the same manner as in Comparative Example 5, except that a thermosetting adhesive film 1 was used as a thermosetting adhesive film, the evaluation was performed. While continuity was rated “A” as a result of the evaluation, cross-sectional observation was rated “C”. The results are shown in Table 1.

### Comparative Example 7

In the same manner as in Example 15, except that a fluororesin film having a thickness of 30 μm was used as a protective film, the evaluation was performed. The results are shown in Table 1.

TABLE 1

| | Protective film | | | | | |
|---|---|---|---|---|---|---|
| | | Film | Thermal | Insulating | Evaluation | Evaluation of |
| | | thickness | conductivity | organic | of | cross-sectional |
| | Material | (μm) | (W/mK) | filler | continuity | observation |
| Example 1 | Aluminum | 6 | 230 | Present | A | A |
| Example 2 | Aluminum | 12 | 230 | Present | A | A |
| Example 3 | Aluminum | 20 | 230 | Present | A | A |
| Example 4 | Aluminum | 6 | 230 | Absent | A | A |
| Example 5 | Aluminum | 12 | 230 | Absent | A | A |
| Example 6 | Aluminum | 20 | 230 | Absent | A | A |
| Example 7 | Copper | 3 | 400 | Present | A | A |
| Example 8 | Copper | 5 | 400 | Present | A | A |
| Example 9 | Copper | 18 | 400 | Present | A | A |
| Example 10 | Copper | 30 | 400 | Present | A | B |
| Example 11 | Copper | 3 | 400 | Absent | A | A |
| Example 12 | Copper | 5 | 400 | Absent | A | A |
| Example 13 | Copper | 18 | 400 | Absent | A | A |
| Example 14 | Copper | 30 | 400 | Absent | A | A |
| Example 15 | Aluminum | 12 | 400 | Present | A | A |
| Comparative | Fluororesin | 12 | 0.25 | Present | C | C |
| Example 1 | | | | | | |
| Comparative | Fluororesin | 30 | 0.25 | Present | C | C |
| Example 2 | | | | | | |
| Comparative | Fluororesin | 12 | 0.25 | Absent | B | C |
| Example 3 | | | | | | |
| Comparative | Fluororesin | 30 | 0.25 | Absent | C | C |
| Example 4 | | | | | | |
| Comparative | Iron | 20 | 70 | Present | C | C |
| Example 5 | | | | | | |
| Comparative | Iron | 20 | 70 | Absent | A | C |
| Example 6 | | | | | | |
| Comparative | Fluororesin | 30 | 0.25 | Present | C | C |
| Example 7 | | | | | | |

### REFERENCE SIGNS LIST

1 Heat tool
2 Protective film
3 Semiconductor chip
4 Thermosetting adhesive layer
5 Substrate
6 Stage
7 Copper pillar
8 Solder bump
9 Electrode pad
10 Plastic film
11 Through-silicon via (TSV)
12 Supply reel
13 Take-up reel

### INDUSTRIAL APPLICABILITY

According to the production method of the present invention, it becomes possible to easily make solder joints between bumps and electrode pads through an adhesive film, thus enabling the production of a semiconductor device in high yield.

The present invention is suited for the production of a semiconductor device in which solder joints are made between semiconductor chips such as Ics and LSIs, and circuit substrates such as a flexible substrate, a glass epoxy substrate, a glass substrate, a ceramics substrate, a silicon interposer, and a silicon substrate, or the production of a semiconductor chip laminate in which solder joints are made between semiconductor chips.

1. A method for producing a semiconductor device in which solder joints are made between a semiconductor chip with bumps and a substrate with electrodes corresponding to the bumps through a thermosetting adhesive layer, the method comprising the successive steps of:
(A) forming a thermosetting adhesive layer in advance on a surface including bumps of the semiconductor chip;
(B) laying a surface on the thermosetting adhesive layer side of the semiconductor chip, on which the thermosetting adhesive layer is formed, and a substrate one upon another, followed by pre-bonding using a heat tool to obtain a pre-bonded laminate; and
(C) interposing a protective film having a thermal conductivity of 100 W/mK or more between the heat tool and a surface on the semiconductor chip side of the pre-bonded laminate, melting a solder between the semiconductor chip and the substrate and simultaneously curing the thermosetting adhesive layer using the heat tool.

2. The method for producing a semiconductor device according to claim 1, wherein solder joints are made between a plurality of semiconductor chips with bumps and through-silicon vias, and a substrate including electrodes corresponding to the bumps through a thermosetting adhesive layer, the method including the successive steps of:
(A′) forming a thermosetting adhesive layer in advance on each surface including bumps of a plurality of semiconductor chips to obtain a plurality of semiconductor chips on which the thermosetting adhesive layer is formed,
(B′) obtaining a multistage pre-bonded laminate by passing through the step of laying a surface on the thermosetting adhesive layer side, on which the thermosetting adhesive layer is formed, of one semiconductor chip and a substrate one upon another, followed by pre-bonding using a heat tool, and one or more step(s) of laying a surface on the semiconductor chip side of the semiconductor chips and a surface on the thermosetting adhesive layer side of the other semiconductor chips, on which the thermosetting adhesive layer is formed, one upon another, followed by pre-bonding using a heat tool, and
(C′) interposing a protective film having a thermal conductivity of 100 W/mK or more between the heat tool and a surface on the semiconductor chip side of the multistage pre-bonded laminate, melting a solder between a plurality of semiconductor chips, and a solder between the semiconductor chips and the substrate, and simultaneously curing the thermosetting adhesive layer using the heat tool.

3. The method for producing a semiconductor device according to claim 1, wherein a thermosetting adhesive film is laminated in advance on a surface including bumps of the semiconductor chip to form a thermosetting adhesive layer in the step (A).

4. The method for producing a semiconductor device according to claim 2, wherein the thermosetting adhesive film is laminated in advance on each surface including bumps of a plurality of semiconductor chips to form a thermosetting adhesive layer in the step (A′).

5. The method for producing a semiconductor device according to claim 1, wherein the thermosetting adhesive layer contains an insulating inorganic filler.

6. The method for producing a semiconductor device according to claim 1, wherein the protective film is an aluminum foil or a copper foil.

7. The method for producing a semiconductor device according to claim 1, wherein the substrate is a silicon substrate.

8. The method for producing a semiconductor device according to claim 1, wherein the protective film is supplied in a reel-to-reel manner.

9. An apparatus for producing a semiconductor device by bonding a substrate with a semiconductor chip, comprising a bonding device including a stage for disposing the substrate and a heat tool having a mechanism for heating and pressurizing the semiconductor chip; a supply reel for supplying a protective film having a thermal conductivity of 100 W/mK or more; and a take-up reel for taking up the protective film; which are disposed so that the protective film supplied from the supply reel passes between the heat tool and the stage, thus being taken up by the take-up reel.
